(19) United States
(12) Patent Application Publication
(10) Pub. No.: US 2024/0304515 A1
(43) Pub. Date: Sep. 12, 2024

(54) HIGH THERMAL DISSIPATION FEATURES FOR A FLIP CHIP STRUCTURE

(71) Applicant: Western Digital Technologies, Inc., San Jose, CA (US)

(72) Inventors: Xuyi Yang, Shanghai (CN); Yiqin Huang, Shanghai (CN); Zengyu Zhou, Shanghai (CN); Kandy Sun, Shanghai (CN); Jerry Tang, Shanghai (CN); Gang Liu, Shanghai (CN); Cong Zhang, Shanghai (CN); Hope Chiu, Shanghai (CN)

(21) Appl. No.: 18/357,211

(22) Filed: Jul. 24, 2023

Related U.S. Application Data
(60) Provisional application No. 63/489,266, filed on Mar. 9, 2023.

(51) Int. Cl. H01L 23/373; H01L 21/48; H01L 23/00; H01L 23/498; H01L 25/00; H01L 25/065

(52) U.S. Cl. CPC H01L 23/3735; H01L 21/486; H01L 23/49816; H01L 23/49838; H01L 24/16; H01L 24/32; H01L 24/73; H01L 25/0652; H01L 25/50; H01L 24/48; H01L 2224/16225; H01L 2224/32225; H01L 2224/48105; H01L 2224/48145; H01L 2224/48225; H01L 2224/73204; H01L 2225/065; H01L 2924/1438; H10B 80/00

(57) ABSTRACT

A semiconductor package having various thermal dissipation features to dissipate heat. The semiconductor package may include an integrated circuit and a non-volatile storage device. Vias may be formed in the substrate and filled with a thermal conductive material. A pyrolytic graphite sheet overlays a top surface of the substrate and the vias. The pyrolytic graphite sheet defines one or more openings that enable the integrated circuit and the non-volatile storage device to be coupled to the top surface of the substrate. The integrated circuit is covered by another thermal conductive material such as a copper or silver paste. The copper or silver paste also covers a sidewall of the pyrolytic graphite sheet. The semiconductor package is enclosed by molding material and a metal layer. The pyrolytic graphite sheet connects the metal layer and the thermal conductive material overlaying the integrated circuit to form various thermal dissipation paths.

### CROSS-REFERENCE TO RELATED APPLICATIONS

The present application claims priority to U.S. Provisional Application No. 63/489,266 entitled “HIGH THERMAL DISSIPATION FEATURES FOR A FLIP CHIP STRUCTURE”, filed Mar. 9, 2023, the entire disclosure of which is hereby incorporated by reference in its entirety.

### BACKGROUND

An increasing number of electronic devices use various semiconductor chips to process and store data. As demand for semiconductor chips increases, so do the demands for higher density, smaller size and higher performance. However, higher performance typically means faster circuits, and faster circuits typically consume more power. Consumption of more power in a smaller space raises temperatures, and high temperatures may negatively impact the performance and/or the reliability of the semiconductor chips.

Accordingly, it would be beneficial for a semiconductor chip to have thermal dissipation features that effectively and efficiently dissipate heat from the semiconductor chip without increasing size of the semiconductor chip or sacrificing the performance of the semiconductor chip.

### SUMMARY

The present application describes a semiconductor chip or semiconductor package having improved thermal dissipation features when compared with current semiconductor package thermal dissipation solutions. In an example, the semiconductor package described herein is a flip chip system in a package (SiP) that may include one or more integrated circuits and/or one or more non-volatile storage devices. A substrate of the semiconductor package includes one or more vias that are filled with a thermal conductive material such as, for example, copper or silver. A pyrolytic graphite sheet (PGS) or other thermal conductive material is provided on a top surface of the substrate next to the integrated circuit. At least a portion (e.g., a sidewall) of the pyrolytic graphite sheet is covered by a silver paste, a copper paste or other thermal conductive material that also overlays the integrated circuit. In an example, the semiconductor package is at least partially surrounded or enclosed by a metal layer. The pyrolytic graphite sheet connects the metal layer and the thermal conductive material overlaying the integrated circuit to form various thermal dissipation paths. As such, any heat generated by the integrated circuit can be transferred from the integrated circuit to the vias and the metal layer via the pyrolytic graphite sheet.

Accordingly, the present application describes a semiconductor package that includes a substrate and an integrated circuit electrically coupled to a surface of the substrate. A first thermal conductive material is provided on the surface of the substrate and defines at least a first opening which enables the integrated circuit to be electrically coupled to the surface of the substrate. A second thermal conductive material that is different from the first thermal conductive material at least partially overlays the integrated circuit. The second thermal conductive material also overlays at least a corner of the first opening defined by the first thermal conductive material.

Also described is a method for fabricating a semiconductor package. In an example, the method includes forming a plurality of vias in a substrate. A first thermal conductive material is laminated on a surface of the substrate. In an example, the first thermal conductive material defines at least one opening and covers the plurality of vias. A integrated circuit is electrically coupled to the surface of the substrate within the at least one opening defined by the first thermal conductive material. A second thermal conductive material is dispensed on the integrated circuit and the first thermal conductive material such that the second thermal conductive material at least partially overlays the integrated circuit and at least a corner of the at least one opening defined by the first thermal conductive material.

Another example relates to a semiconductor package. In this example, the semiconductor package includes a substrate and an integrated circuit electrically coupled to a surface of the substrate. A bonding area associated with the NAND die stack is electrically coupled to the surface of the substrate and the NAND die stack is coupled to the integrated circuit. A first thermal conductive material is also provided on the surface of the substrate. The first thermal conductive material defines a first opening to enable the integrated circuit to be electrically coupled to the surface of the substrate and defines a second opening to enable the NAND die stack to be electrically coupled to the surface of the substrate. A second thermal conductive material that is different from the first thermal conductive material at least partially overlays the integrated circuit. Additionally, the second thermal conductive material overlays at least a corner of the first opening defined by the first thermal conductive material.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates an example of an existing flip chip structure having a thermal dissipation feature.

FIG. 2 illustrates a flip chip structure having various thermal dissipation features according to an example.

FIG. 3 illustrates thermal dissipation paths provided by the thermal dissipation features shown and described with respect to FIG. 2 according to an example.

FIG. 4A-FIG. 4K illustrate various operations for fabricating a flip chip structure having various thermal dissipation features according to an example.

FIG. 5 illustrates another flip chip structure having various thermal dissipation features according to an example.

FIG. 6 illustrates thermal dissipation paths provided by the thermal dissipation features of the flip chip structure shown and described with respect to FIG. 5 according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. The following detailed description is therefore not to be taken in a limiting sense, and the scope of the present disclosure is defined by the appended claims and their equivalents.

As indicated above, an increasing number of electronic devices use various semiconductor chips to process and store data. In addition to the increased demand, there is also a demand for higher density, smaller size and higher performance. However, higher performance, higher density and smaller size may cause certain obstacles to arise. For example, higher performance typically means faster circuits, and faster circuits typically consume more power. As more power is consumed, especially in smaller spaces, the temperature of the semiconductor chips rise. Higher temperatures may negatively impact the performance and/or the reliability of the semiconductor chips.

In order to address the above, the present disclosure describes various thermal dissipation features for semiconductor chips. The thermal dissipation features described herein may effectively and efficiently dissipate heat from the semiconductor chip without increasing the overall size of the semiconductor chip or sacrificing the performance of the semiconductor chip. In the examples described herein, the semiconductor chip or the semiconductor package is a flip chip system in a package (SiP). While a flip chip package/structure is described, some or all of the thermal dissipation features may be used in other semiconductor chips.

The flip chip structure described herein includes one or more integrated circuits and/or one or more non-volatile storage devices. The one or more non-volatile storage devices may include one or more NAND dies that are stacked and/or communicatively coupled together. A substrate of the flip chip structure includes one or more vias that are filled with a thermal conductive material such as, for example, copper or silver. A pyrolytic graphite sheet (PGS) or other thermal conductive material is provided on a top surface of the substrate and overlays the vias. The pyrolytic graphite sheet partially or substantially covers a surface of the substrate and the vias. However, the pyrolytic graphite sheet may also define one or more openings that enables the one or more integrated circuits and/or the one or more non-volatile storage devices to be coupled to the surface of the substrate. The integrated circuit may be covered by another thermal conductive material such as, for example, copper or silver. Additionally, the silver or copper may also cover at least a sidewall of the pyrolytic graphite sheet. In an example, the sidewall of the pyrolytic graphite sheet is defined by, or is otherwise associated with, the opening defined by the pyrolytic graphite sheet.

The flip chip structure is also at least partially surrounded or enclosed by molding material and a metal layer. The pyrolytic graphite sheet connects the metal layer and the thermal conductive material overlaying the integrated circuit to form various thermal dissipation paths. As such, any heat generated by the integrated circuit can be transferred from the integrated circuit to the vias and the metal layer via the pyrolytic graphite sheet.

In accordance with the above, many technical benefits may be realized including, but not limited to, better/higher thermal dissipation properties of semiconductor packages when compared to current solutions; lower operating temperatures of semiconductor packages without negatively impacting the performance of the semiconductor packages; and maintaining or decreasing the size/dimensions of semiconductor packages while improving the thermal dissipation properties of semiconductor packages.

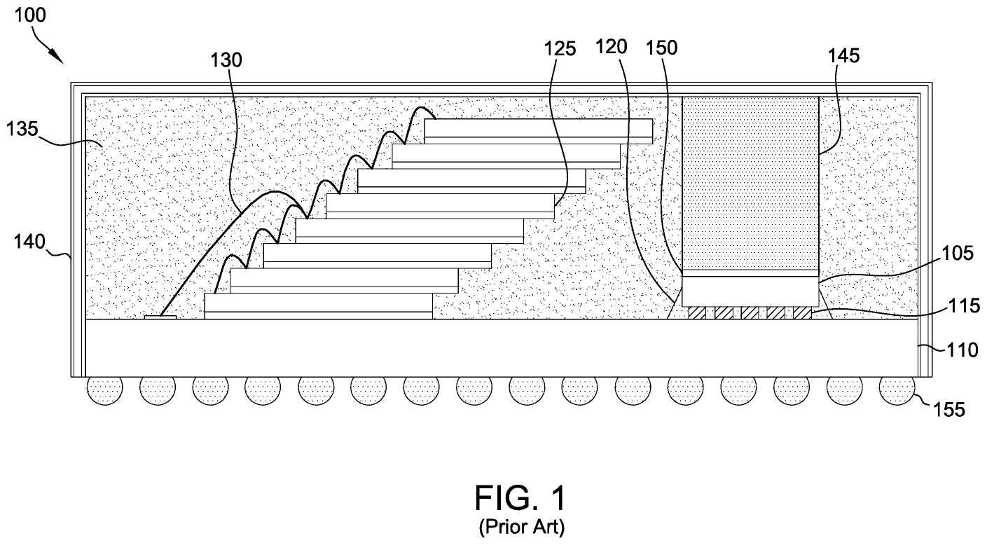

These and other examples will be explained in greater detail below with respect to FIG. 1-FIG. 6.

FIG. 1 illustrates an example of an existing flip chip structure 100 having a thermal dissipation feature. In the example shown in FIG. 1, the flip chip structure 100 includes an integrated circuit 105 (e.g., a controller) mounted on a substrate 110. The integrated circuit 105 may be mounted to the substrate 110 by one or more bumps and/or copper pillars 115. An underfill 120 is also used to further secure the integrated circuit 105 to the substrate 110.

The flip chip structure 100 may also include a non-volatile memory stack 125 or other memory device. The non-volatile memory stack 125 may be electrically and/or communicatively coupled to the substrate 110 using a bond wire 130. The flip chip structure 100 also includes a spacer 145 that is coupled to (e.g., via an adhesive 150 or other material) the integrated circuit 105.

In the existing flip chip structure 100, the spacer 145 extends from the top of the integrated circuit 105 to a metal layer 140 that encloses the flip chip structure 100. The spacer 145 is used to expose the surface of the integrated circuit 105 to the metal layer 140 to enlarge a heat dissipation area of the flip chip structure 100. The flip chip structure 100 may also include a molding compound 135 (e.g., an epoxy molding compound) that has heat dissipation characteristics.

As also shown in FIG. 1, the flip chip structure 100 may also include a plurality of solder balls 155. The solder balls 155 enable the flip chip structure 100 to be electrically and/or communicatively coupled to another substrate.

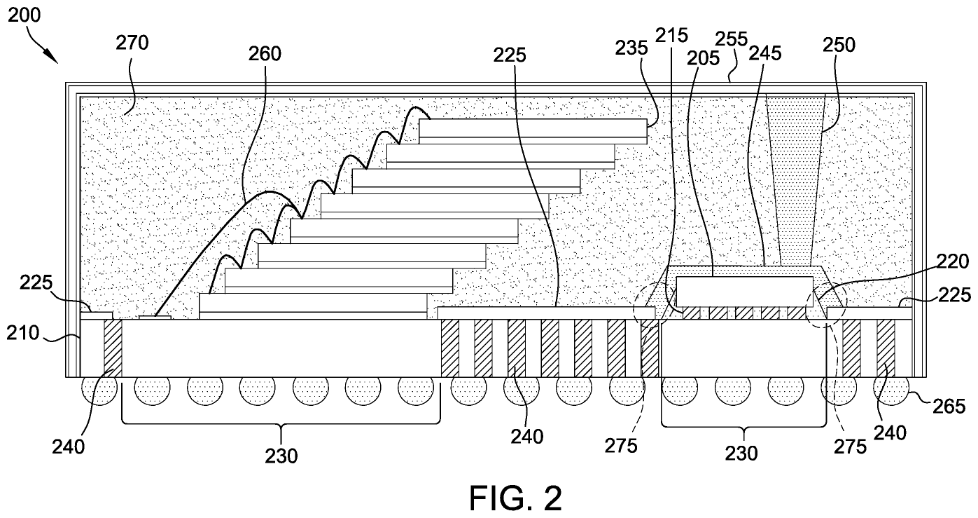

FIG. 2 illustrates a flip chip structure 200 having various thermal dissipation features according to an example. The thermal dissipation features shown in FIG. 2 are an improvement to existing thermal dissipation structures/features of the flip chip structure 100 shown and described with respect to FIG. 1. In some examples, the dimensions of the flip chip structure 200 may be the same or similar to the flip chip structure 100. Thus, the various thermal dissipation features described herein may be implemented in various flip chip structures without sacrificing size, density or performance. For example, the thermal dissipation features shown and described with respect to FIG. 2 reduce the operating temperature of the integrated circuit 205 by four degrees Centigrade or more when compared with current solutions.

In the example shown in FIG. 2, the flip chip structure 200 includes an integrated circuit 205 and a non-volatile memory stack 235. The non-volatile memory stack 235 may include two or more NAND dies that are stacked and/or communicatively coupled via a bond wire 260. As such, the non-volatile memory stack 235 may be referred to herein as a NAND die stack. Although NAND dies are specifically mentioned, the non-volatile memory stack 235 may include any type of volatile or non-volatile memory devices.

The integrated circuit 205 may be a controller or some other application-specific integrated circuit. The integrated circuit 205 may be electrically and/or communicatively coupled to a substrate 210 via one or more bumps and/or copper pillars 215. For example, the integrated circuit 205 may be a flip chip device or other electronic component.

In examples in which the integrated circuit 205 is electrically coupled to the substrate 210 using one or more bumps and/or copper pillars 215, an underfill 220 may be used to further secure the integrated circuit 205 to the substrate 210. The underfill 220 may be an epoxy resin or other material that links or otherwise secures the integrated circuit 205 to the substrate 210 and/or provides protection to the bumps and/or copper pillars 215.

The flip chip structure 200 also includes a number of different thermal dissipation features. For example, the flip chip structure 200 includes a first thermal conductive material 225 and a second thermal conductive material 245. The first thermal conductive material 225 may be laminated on the substrate 210. In an example, the first thermal conductive material substantially covers a first surface (e.g., a top surface) of the substrate 210. The first thermal conductive material 225 may be a pyrolytic graphic sheet (PGS) and have a thickness of between approximately fifteen microns to approximately one hundred microns. Although specific thicknesses are used, the first thermal conductive material 225 may have a number of different thicknesses. In some examples, the PGS may be a multilayer structure. For example, the PGS may include a Graphene layer that is covered by a single adhesive layer or multiple adhesive layers.

In some examples and depending on the design/layout of the flip chip structure 200, the first thermal conductive material 225 may define one or more openings 230. Each of the one or more openings 230 exposes portions of the first surface of the substrate 210 and enables various structures and/or circuits to be communicatively and/or electrically coupled to the substrate 210. In another example, one (or more) structure may be coupled to an exposed surface of the substrate 210 while one (or more) other structures (e.g., the non-volatile memory stack 235) may be coupled to a surface of the PGS.

In the example shown in FIG. 2, the first thermal conductive material 225 defines a first opening and a second opening (represented as openings 230). As previously explained, the openings 230 expose portions of the first surface of the substrate 210 which enables various structures to be coupled to the substrate 210. For example, a non-volatile memory stack 235 and/or an associated wire bonding area is coupled to the top surface of the substrate 210 within the first opening 230. For example, the non-volatile memory stack 235 may be coupled to the substrate 210 using a die attach film (DAF) or other material. Additionally, the integrated circuit 205 may be coupled to the top surface of the substrate 210 within the second opening 230. Although two openings 230 are shown and described, the first thermal conductive material 225 may define any number of openings 230. Additionally, the dimensions and/or locations of the openings 230 may vary based on the design of the flip chip structure 200. Although the integrated circuit 205 and the non-volatile memory stack 235 are shown and described as being positioned within the openings 230, the first thermal conductive material 225 may define openings 230 for other/additional circuits/structures. In other examples, the non-volatile memory stack 235 may be coupled to the first thermal conductive material 225 while a bond pad or bonding area associated with the non-volatile memory stack 235 is coupled to the substrate 210.

The substrate 210 may also include or define one or more vias 240. The vias 240 may extend from the first surface (or top surface) of the substrate 210 to a second surface (or bottom surface) of the substrate 210. In some examples, the vias 240 may be positioned at any location within the substrate 210. In other examples, the vias 240 are positioned below the first thermal conductive material 225 but not under the openings 230 defined by the first thermal conductive material 225.

Each of the one or more vias 240 may be filled with a thermal conductive material to further help dissipate heat from the flip chip structure 200. In an example, the thermal conductive material is copper. In another example, the thermal conductive material is silver. Although copper and silver are specifically mentioned, other materials may be used.

The flip chip structure 200 also includes a second thermal conductive material 245. The second thermal conductive material 245 may be different from the first thermal conductive material 225. For example, the first thermal conductive material 225 may be a pyrolytic graphite sheet and the second thermal conductive material 245 may be a silver paste, a copper paste or another a material having good thermal conductivity and good fluidity.

During a flip chip structure fabrication process, the second thermal conductive material 245 may be dispensed or otherwise placed over the integrated circuit 205 and/or the underfill 220. For example, the second thermal conductive material 245 may partially cover one or more surfaces of the integrated circuit 205 and/or the underfill 220, substantially cover one or more surfaces of the integrated circuit 205 and/or the underfill 220 or entirely cover one or more surfaces of the integrated circuit 205 and/or the underfill 220.

In some examples, as the second thermal conductive material 245 is dispensed or otherwise placed over the integrated circuit 205 and/or the underfill 220, the second thermal conductive material 245 may flow onto or into one or more of the vias 240, thereby forming various thermal dissipation paths.

The second thermal conductive material 245 may also overlay, partially overlay, substantially overlay, contact, cover, partially cover or substantially cover at least a corner, a sidewall, an edge or other surface of one or more of the openings 230 defined by the first thermal conductive material 225. For example and as shown in FIG. 2, the second thermal conductive material 245 substantially or entirely covers a sidewall of the first thermal conductive material 225 (shown by dashed circles 275). The sidewall of the first thermal conductive material 225 may be exposed or otherwise defined based, at least in part, by the opening 230 that contains or is otherwise associated with the integrated circuit 205.

While some of the second thermal conductive material 245 may be dispensed on a top surface of the first thermal conductive material 225, the first thermal conductive material may have better heat dissipation properties in the XY direction when compared to the Z direction. Hence, it would be beneficial for the second thermal conductive material 245 to cover (or substantially cover) the sidewall of the first conductive material 225.

The flip chip structure 200 may also include a molding material 270 or a molding compound. The molding material 270 may be any suitable molding material (e.g., an epoxy molding compound) having heat dissipation properties. The molding material 270 may be used to encase the non-volatile memory stack 235, the bond wire 260 associated with the non-volatile memory stack 235, the first thermal conductive material 225 and the second thermal conductive material 245.

In order to further assist with heat dissipation, the molding material 270 may define a channel 250. In some examples, the channel 250 may be formed within the molding material 270. The channel 250 may extend from the second thermal conductive material 245 (e.g., a top surface of the second thermal conductive material 245, a side surface of the second thermal conductive material 245) to an outside surface of the molding material 270 and contact a multi-metal layer 255 that encases the flip chip structure 200. In an example, the multi-metal layer 255 acts as a thermal dissipation layer.

Additionally and as shown in FIG. 2, the first thermal conductive material 225 (e.g., a sidewall of the first thermal conductive material 225) also contacts an inner surface of the multi-metal layer 255. As such, the first thermal conductive material 225 forms heat dissipation paths between the integrated circuit 205 and the multi-metal layer 255 (e.g., via the second thermal conductive material 245).

The multi-metal layer 255 may be created using a sputtering process. In another example, the multi-metal layer 255 may be created by plating one or more electrical/chemical materials on the molding material 270. In an example, the multi-metal layer 255 may be comprised of one or more SUS (e.g., FR4, aluminum, and/or stainless steel) layers and one or more copper layers (e.g., sandwiched between multiple SUS layers). In another example, the multi-metal layer 255 may include one or more tin layers, one or more copper layers, one or more nickel layers and/or one or more aluminum layers. Although specific layers/materials are mentioned, the multi-metal layer 255 may be comprised of any metal material having good thermal/electrical conductivity and adhesion properties (thereby enabling the multi-metal layer 255 to adhere to the molding material 270). In an example, and depending on the material used, the multi-metal layer 255 may act as a thermal dissipation layer and as an electro-magnetic interference (EMI) layer.

The flip chip structure 200 may also include one or more solder balls 265 disposed on a bottom surface of the substrate 210. The solder balls 265 may be arranged in a grid or pattern and enable the flip chip structure 200 to be electrically and/or communicatively coupled to another substrate or structure.

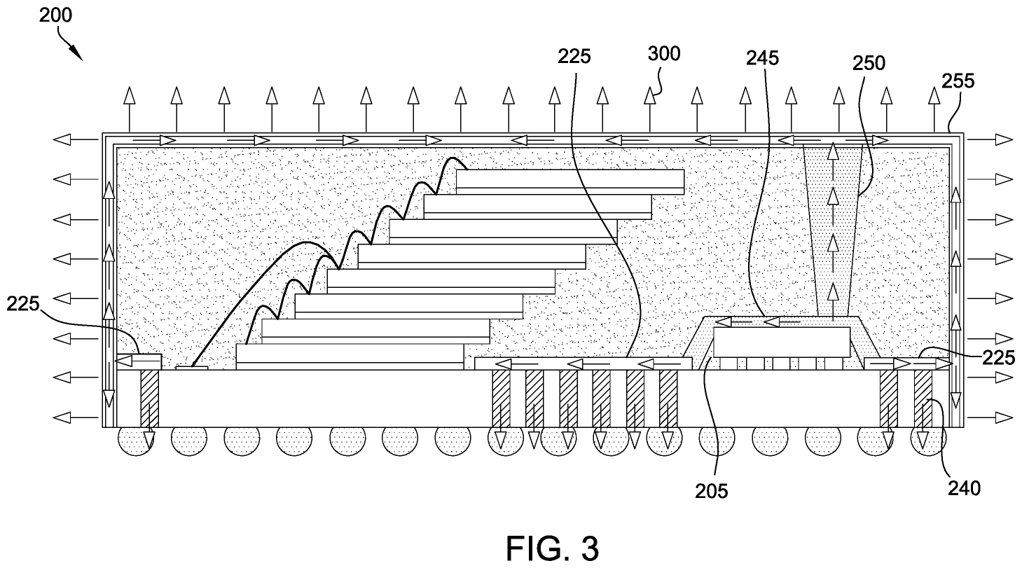

FIG. 3 illustrates thermal dissipation paths provided by the thermal dissipation features of the flip chip structure 200 shown and described with respect to FIG. 2 according to an example. In FIG. 3, the heat dissipation paths are illustrated by the arrows 300.

As explained above, the first thermal conductive material 225 forms a heat dissipation path between the second thermal conductive material 245 and the multi-metal layer 255. Additionally, various heat dissipation paths may be formed between the first thermal conductive material 225 and the vias 240. In examples, the thermal conductivity of the first thermal conductive material 225 and the second thermal conductive material 245 is much higher than the DAF and the dies of the non-volatile memory stack 235. Thus, any heat generated by the integrated circuit 205 may be effectively and efficiently transferred away from the integrated circuit 205 and the non-volatile memory stack 235 and out of the flip chip structure 200 such as shown by the arrows 300.

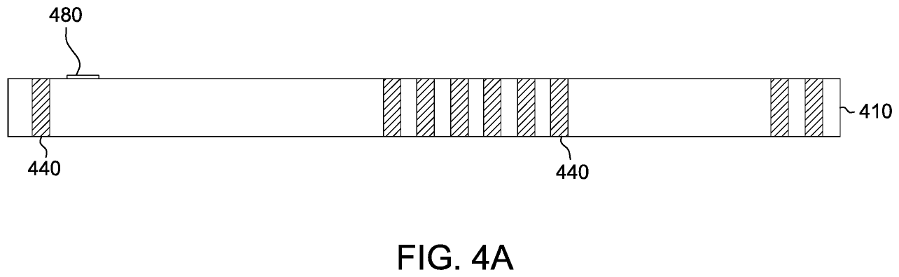

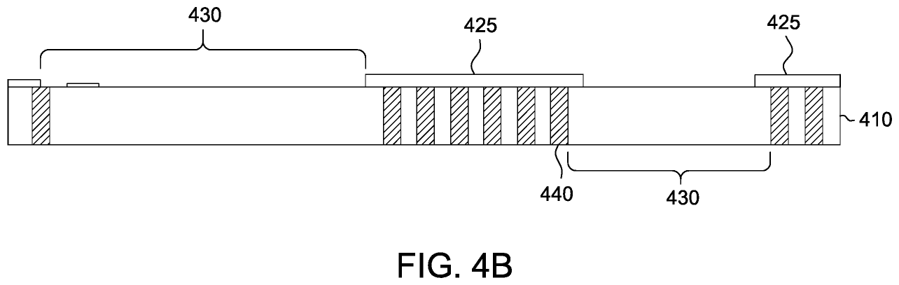

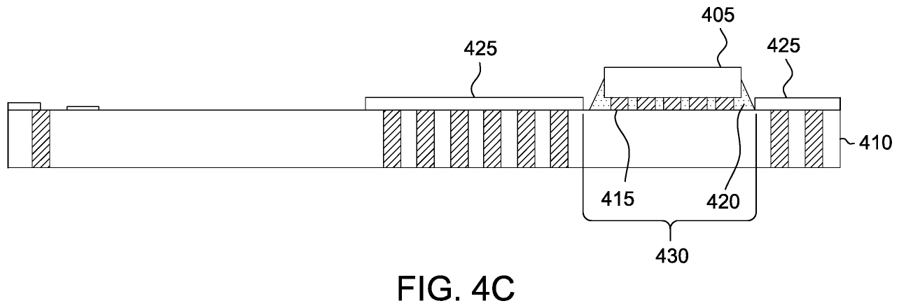

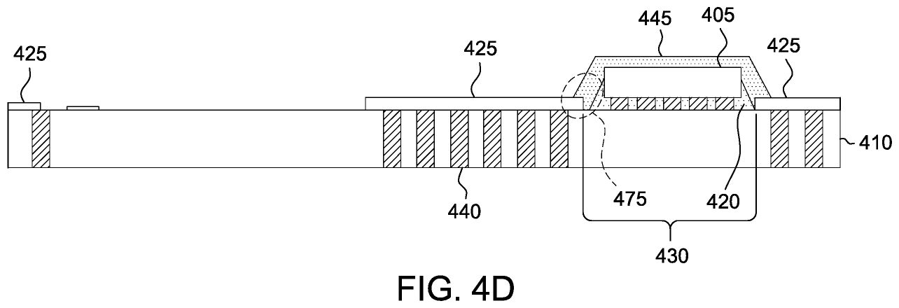

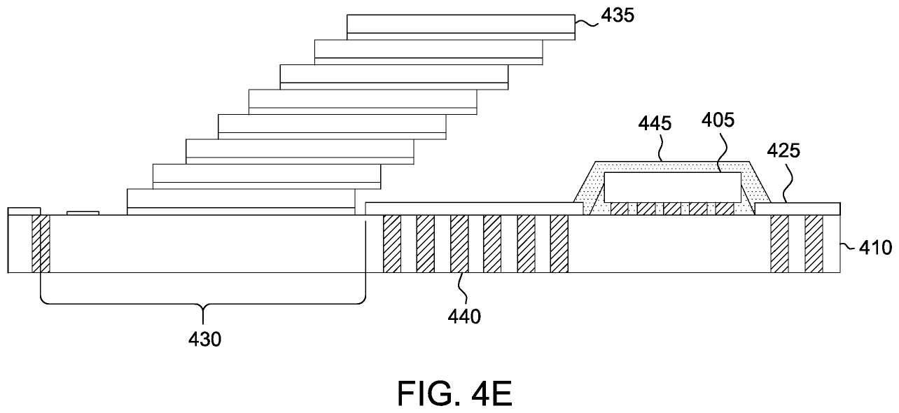

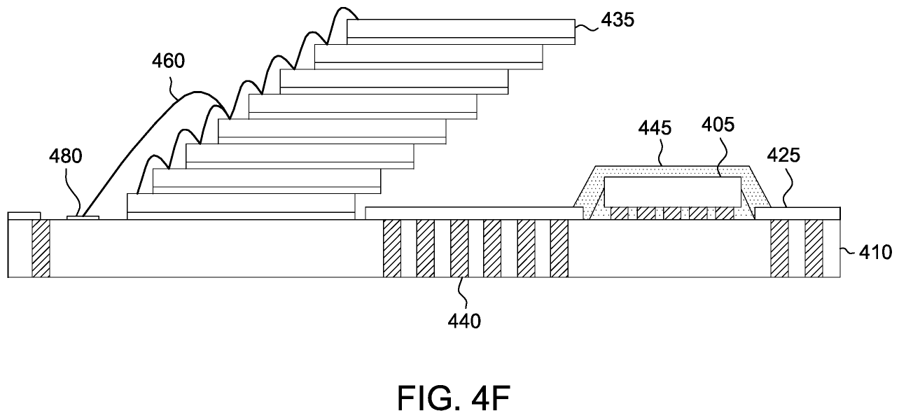

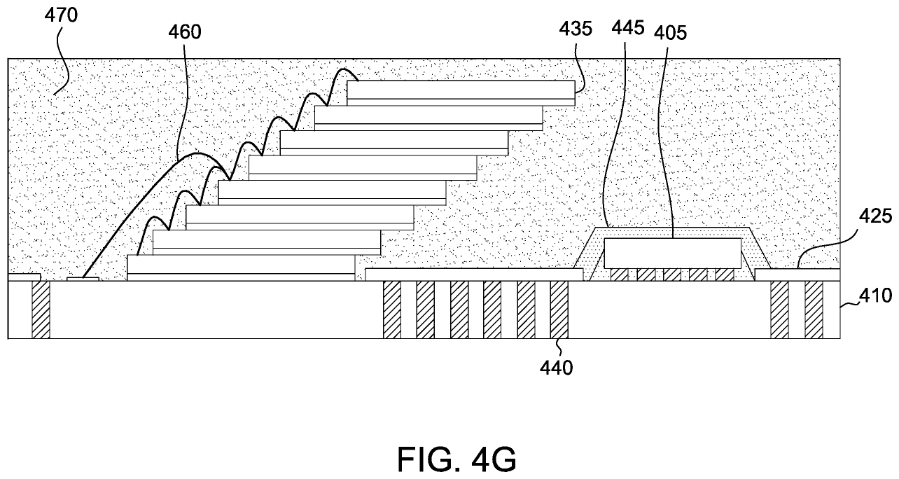

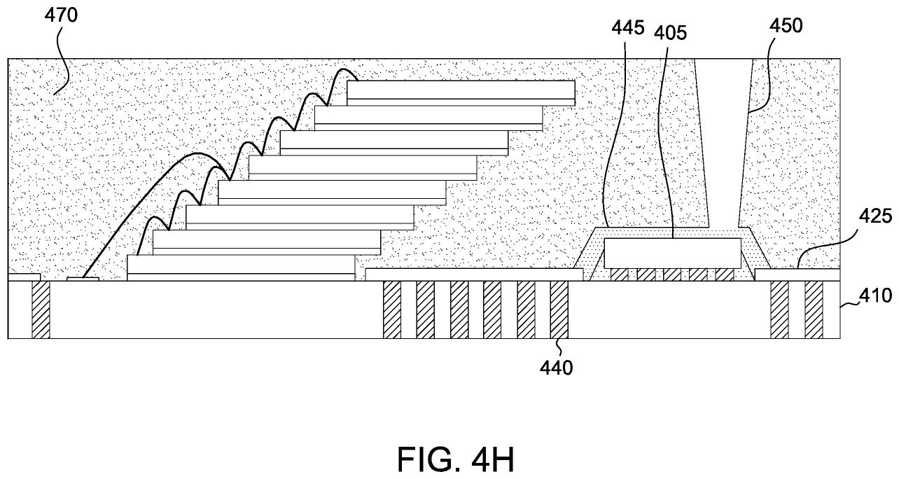

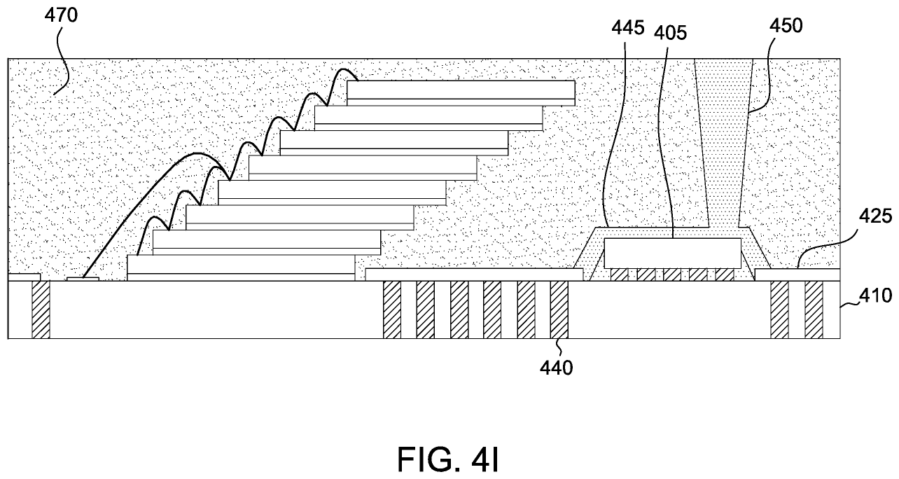

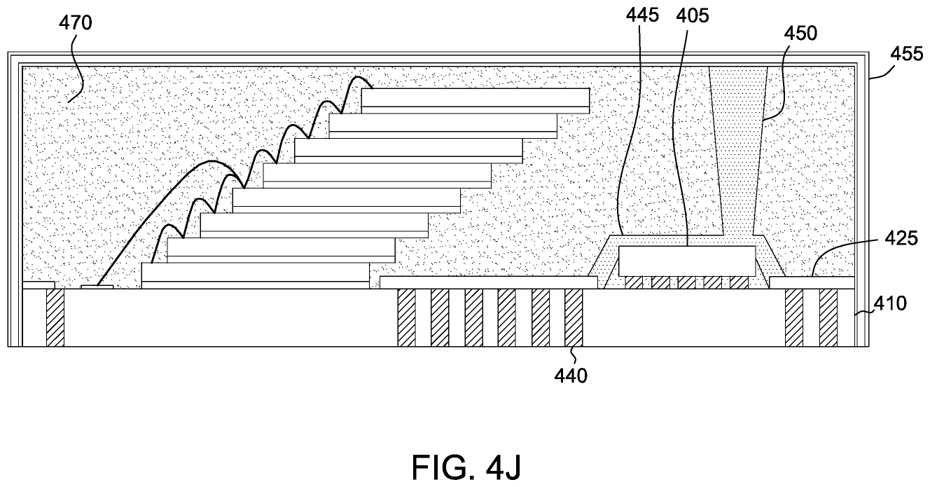

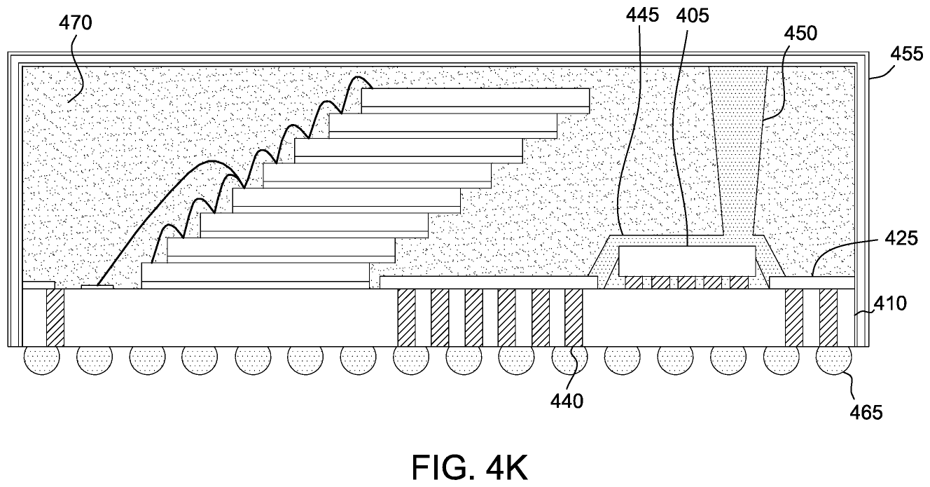

FIG. 4A-FIG. 4K illustrate various operations for fabricating a flip chip structure having various thermal dissipation features according to an example. In an example, the flip chip structure 400 (FIG. 4K) is similar to the flip chip structure 200 shown and described with respect to FIG. 2 and FIG. 3. In the explanation of FIG. 4A-FIG. 4K, some of the reference numbers are included in the various figures for additional reference/context.

In a first operation shown in FIG. 4A, a substrate 410 is prepared. In an example, the substrate 410 is a high thermal substrate and may be comprised of multiple layers. As part of the preparation process, a bond pad 480 may be provided on a first surface of the substrate 410. Additionally, one or more vias 440 may be formed in or otherwise defined by the substrate 410. The vias 440 may be filled with a thermal conductive material such as, for example, silver or copper. In an example, the vias 440 are formed in the substrate 410 at locations that will subsequently be overlayed by a first thermal conductive material.

For example and as shown in FIG. 4B, a first thermal conductive material 425 is laminated or is otherwise provided on a first surface (e.g., a top surface) of the substrate 410. The first thermal conductive material 425 may be a pyrolytic graphite sheet or other thermal conductive material. The first thermal conductive material 425 may define one or more openings 430 that expose one or more areas on the first surface of the substrate 410. Additionally, the first thermal conductive material 425 overlays the various vias 440 formed in or otherwise defined by the substrate 410.

Once the first thermal conducive material 425 has been provided on the substrate 410, an integrated circuit 405 is communicatively and/or electrically coupled to the substrate 410 such as shown in FIG. 4C. In an example, the integrated circuit 405 is a flip chip die. As such, the integrated circuit 405 may be communicatively and/or electrically coupled to the substrate 410 via one or more solder bumps and/or copper pillars 415. An underfill 420 may be used to further secure the integrated circuit 405 to the substrate 410. As also shown in FIG. 4C, the integrated circuit is communicatively and/or electrically coupled to the substrate in an opening 430 defined by the first thermal conductive material 425.

As shown in FIG. 4D, a second thermal conductive material 445 is dispensed over the integrated circuit 405. In an example, the second thermal conductive material 445 may partially cover, substantially cover or entirely cover the integrated circuit 405 and the underfill 420. The second thermal conductive material 445 may also substantially or entirely cover a sidewall of the first thermal conductive material 425 (shown by the dashed circle 475). The sidewall of the first thermal conductive material 425 may be exposed or otherwise defined based, at least in part, by the opening 430 that contains or is otherwise associated with the integrated circuit 405. The second thermal conductive material 445 may also flow into one or more of the vias 440 (provided that the one or more vias 440 do not already contain a thermal conductive material and/or are not covered by the first thermal conductive material 445).

FIG. 4E illustrates how a non-volatile memory stack 435 is coupled to or otherwise provided on the first surface of the substrate 410. As shown, the non-volatile memory stack 435 is coupled to the substrate 410 in another opening 430 defined by the first thermal conductive material 425. In an example, the non-volatile memory stack 435 includes one or more NAND dies that are coupled to the substrate 410 and/or to each other using a die attach film (DAF) or other adhesive.

As shown in FIG. 4F, a bond wire 460 is used to communicatively coupled each die of the non-volatile memory stack 435 to each other and to the bond pad 480. In an example, any suitable wire bonding process may be used.

FIG. 4G illustrates that a molding material 470 may be used to encase the non- volatile memory stack 435, the bond wire 460 associated with the non-volatile memory stack 235, the first thermal conductive material 225, the second thermal conductive material 245 and/or any exposed surface of the first surface of the substrate 410. The molding material 470 may be any suitable molding material (e.g., an epoxy molding compound) having heat dissipation properties.

As shown in FIG. 4H, a channel 450 may be formed in or otherwise defined by the molding material 470. In an example, the channel 450 may be formed by a drill (e.g., laser drill) or an etching process. In another example, during a molding process, a mold chase can be designed to include a pillar/channel 450. As such, after the chase is released, a mold cap may already have the channel 450.

The channel 450 may extend, in any direction, from a surface of the second thermal conductive material 445 through the molding material 450 to an edge or outside surface of the molding material 470. The channel 450 may have a first dimension at or near the surface of the second thermal conductive material 445 and have a second, larger dimension, at or near the edge or the outside surface of the molding material 470. As shown in FIG. 41, the channel 450 may then be filled with the second thermal conductive material 445 (or another thermal conductive material).

In some examples, a copper plate and/or copper coating may be used in conjunction with the channel 450. For example, once the channel 450 is formed, a metal seed layer (e.g., PVD Ti/Cu) may be formed on the sidewalls of the channel 450 and/or on a top surface of the integrated circuit 405. The channel 450 may then be filled with a copper material or other thermal conductive material.

A multi-metal layer 455 may then be formed around the molding material 470 such as shown in FIG. 4J. The multi-metal layer 455 may be formed using a sputtering process. In another example, the multi-metal layer 455 may be created by plating one or more electrical/chemical materials on the molding material 270. One or more solder balls 465 may then be mounted on a second surface of the substrate 410 such as shown in FIG. 4K.

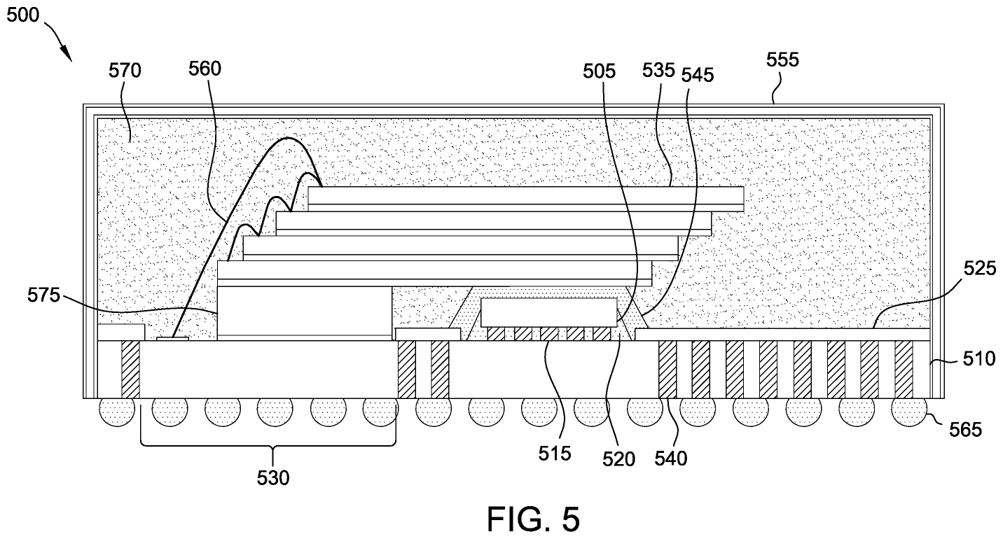

FIG. 5 illustrates another flip chip structure 500 having various thermal dissipation features according to an example. The flip chip structure 500 may have similar components and features as the flip chip structure 200 shown and described with respect to FIG. 2. However, unlike the flip chip structure 200, the flip chip structure 500 includes an embedded integrated circuit 505 (e.g., embedded under a non-volatile memory stack 535).

The integrated circuit 505 may be a semiconductor chip, a controller or some other application-specific integrated circuit. The integrated circuit 505 may be electrically and/or communicatively coupled to a substrate 510 via one or more bumps and/or copper pillars 515. For example, the integrated circuit 505 may be a flip chip device. In another example, the integrated circuit 505 may be electrically and/or communicatively coupled to the substrate 510 using other methodologies.

When the integrated circuit 505 is electrically coupled to the substrate 510 using bumps and/or copper pillars 515, an underfill 520 may be used to further secure the integrated circuit 505 to the substrate 510.

Like the flip chip structure 200 shown and described with respect to FIG. 2, the flip chip structure 500 includes a number of different thermal dissipation features. For example, the flip chip structure 500 includes a first thermal conductive material 525 that is laminated on the substrate 510. The first thermal conductive material 525 may be a pyrolytic graphic sheet (PGS) and have a thickness of between approximately fifteen microns to approximately one hundred microns.

Depending on the design/layout of the flip chip structure 500, the first thermal conductive material 525 may define one or more openings 530 that enables various structures and/or circuits to be communicatively and/or electrically coupled to the substrate 510. In the example shown in FIG. 5, a non-volatile memory stack 535 and/or an associated wire bonding area is coupled to the top surface of the substrate 510 within one opening 530. Additionally, the integrated circuit 505 is coupled to the top surface of the substrate 510 in another opening.

The substrate 510 may also include or define one or more vias 540. The vias 540 may extend from the top surface of the substrate 510 to a bottom surface of the substrate 510.

The vias 540 may be positioned at any location within the substrate 510. In other examples, the vias 540 are positioned below the first thermal conductive material 525.

Each of the vias 540 may be filled with a thermal conductive material to further help dissipate heat from the flip chip structure 500. In an example, the thermal conductive material is copper. In another example, the conductive material is silver. Although copper and silver are specifically mentioned, other materials may be used.

The flip chip structure 500 also includes a second thermal conductive material 545. The second thermal conductive material 545 may be different from the first thermal conductive material 525. For example, the first thermal conductive material 525 may be a pyrolytic graphite sheet and the second thermal conductive material 545 may be a silver paste, a copper paste, or some other material having good thermal conductivity and good fluidity.

During a fabrication process, the second thermal conductive material 545 may be dispensed or otherwise placed over the integrated circuit 505 and/or the underfill 520 such as previously described. In some examples, the second thermal conductive material 545 may flow into one or more of the vias 540, thereby forming thermal dissipation paths. The second thermal conductive material 545 may also overlay, partially overlay, substantially overlay, contact, cover, partially cover or substantially cover at least a corner, edge or surface of one or more of the openings 530 defined by the first thermal conductive material 525 such as previously described.

As indicated above, the flip chip structure 500 includes an integrated circuit 505 and a non-volatile memory stack 535. In this example, at least one of the dies in the non-volatile memory stack 535 is stacked on top of and coupled and/or adhered to (e.g., using die attach film or other adhesive) a top surface second thermal conductive material 545. In this arrangement, the dimensions of the flip chip structure 500 may be reduced when compared with other solutions. Additionally, the second thermal conductive layer 545 may be dispensed on a surface of the integrated circuit 505 which may also connect the sidewall of the first thermal conductive material 525 and the surface of the second thermal conductive material 545. As such, heat generated from the integrated circuit 505 can be rapidly transferred away from the integrated circuit 505.

In order to achieve this arrangement, a spacer 575 may be used. The spacer 575 may have the same height (or a similar height) as the integrated circuit 505 and the second thermal conductive material 545 layer. In an example, a bottom side of the spacer 575 may be coupled to the substrate 510 within the opening 530 defined by the first thermal conductive material 525 while the top side of the spacer 575 may be coupled to a bottom side of the non-volatile memory stack 535 (e.g., a bottom side of a memory die of the non-volatile memory stack 535).

The flip chip structure 500 may also include a molding material 570 or a molding compound. The molding material 570 may be any suitable molding material having heat dissipation properties. The molding material 570 may be used to encase the non-volatile memory stack 535, the bond wire 560 associated with the non-volatile memory stack 535, the spacer 575, the first thermal conductive material 225 and the second thermal conductive material 245.

A multi-metal layer 555 may encase or substantially encase the flip chip structure 500. The multi-metal layer 255 may be created using a sputtering process. In another example, the multi-metal layer 255 may be created by plating one or more electrical/chemical materials on the molding material 570. In an example, and depending on the material used, the multi-metal layer 555 may act as a thermal dissipation layer and as an electro-magnetic interference (EMI) layer.

As shown in FIG. 5, the first thermal conductive material 525 contacts an inner surface of the multi-metal layer 555. As such, the first thermal conductive material 225 forms a heat dissipation path between the integrated circuit 505 and the multi-metal layer 555 (e.g., via the second thermal conductive material 545).

The flip chip structure 500 may also include one or more solder balls 565 disposed on a bottom surface of the substrate 510. The solder balls 565 may be arranged in a grid or pattern and enable the flip chip structure 500 to be electrically and/or communicatively coupled to another substrate or structure.

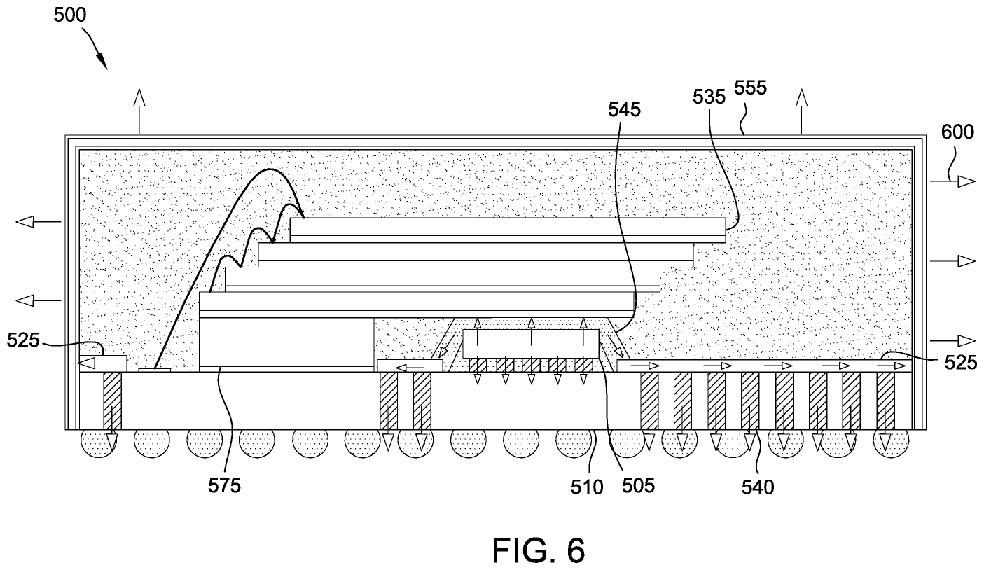

FIG. 6 illustrates thermal dissipation paths provided by the thermal dissipation features of the flip chip structure 500 shown and described with respect to FIG. 5 according to an example. In FIG. 6, the heat dissipation paths are illustrated by the arrows 600.

As explained above, the first thermal conductive material 525 forms a heat dissipation path between the second thermal conductive material 545 and the multi-metal layer 555. Additionally, various heat dissipation paths may be formed between the first thermal conductive material 525 and the vias 540. In examples, the thermal conductivity of the first thermal conductive material 525 and the second thermal conductive material 545 is much higher than the DAF and the memory dies of the non-volatile memory stack 535. Thus, any heat generated by the integrated circuit 505 may be effectively and efficiently transferred away from the integrated circuit 505 and the non-volatile memory stack 535 and out of the flip chip structure 500 such as shown by the arrows 600.

Although the examples described herein are shown and described with respect to a flip chip structure having an integrated circuit and a non-volatile memory stack, the features described herein may be applied to any type of semiconductor product.

In accordance with the above, examples of the present application describe a semiconductor package, comprising: a substrate; an integrated circuit electrically coupled to a surface of the substrate; a first thermal conductive material provided on the surface of the substrate and defining at least one opening to enable the integrated circuit to be electrically coupled to the surface of the substrate; and a second thermal conductive material different from the first thermal conductive material at least partially overlaying the integrated circuit and overlaying at least a sidewall of the at least one opening defined by the first thermal conductive material. In an example, the semiconductor package also includes a plurality of vias defined by the substrate, wherein the plurality of vias are positioned below the first thermal conductive material. In an example, each of the plurality of vias are filled with the second thermal conductive material or a third thermal conductive material. In an example, the semiconductor package also includes a multi-metal layer at least partially enclosing the substrate, the integrated circuit, the first thermal conductive material and the second thermal conductive material, wherein at least a portion of the first thermal conductive material contacts an inner surface of the multi-metal layer. In an example, the semiconductor package also includes a channel extending from the second thermal conductive material, the channel being filled with the second thermal conductive material and contacting the inner surface of the multi-metal layer. In an example, the first thermal conductive material is a pyrolytic graphite sheet. In an example, the second thermal conductive material is selected from a group comprising silver and copper. In an example, the semiconductor package also includes a NAND die stack coupled to the surface of the substrate, wherein the first thermal conductive material defines another opening to enable the NAND die stack to be coupled to the substrate.

The present application also describes a method for fabricating a semiconductor package, comprising: forming a plurality of vias in a substrate; laminating a first thermal conductive material on a surface of the substrate, the first thermal conductive material defining at least one opening and covering the plurality of vias; electrically coupling an integrated circuit to the surface of the substrate within the at least one opening defined by the first thermal conductive material; and dispensing a second thermal conductive material on the integrated circuit and the first thermal conductive material such that the second thermal conductive material at least partially overlays the integrated circuit and at least partially covers a sidewall of the at least one opening defined by the first thermal conductive material. In an example, the method also includes coupling a NAND die stack to the surface of the substrate, the NAND die stack being coupled to the surface of the substrate within a second opening defined by the first thermal conductive material. In an example, the method also includes encapsulating the NAND die stack, the integrated circuit the first thermal conductive material and the second thermal conductive material with a molding material. In an example, the method also includes forming a channel within the molding material. In an example, the method also includes filling the channel with the second thermal conductive material. In an example, the method also includes forming a multi-metal enclosure around at least a portion of the substrate and the molding material such than an inner surface of the multi-metal enclosure contacts the second thermal conductive material within the channel and at least a portion of the first thermal conductive material. In an example, the method also includes providing a plurality of solder balls on a bottom surface of the substrate. In an example, the first thermal conductive material is a pyrolytic graphite sheet. In an example, the second thermal conductive material is selected from a group comprising silver and copper. In an example, the method also includes filling the vias with the second thermal conductive material.

The present disclosure also describes a semiconductor package, comprising: a substrate; an integrated circuit electrically coupled to a surface of the substrate; a NAND die stack is coupled to the integrated circuit; a first thermal conductive material provided on the surface of the substrate and defining a first opening to enable the integrated circuit to be electrically coupled to the surface of the substrate and a second opening to enable a bonding area associated with the NAND die stack to be coupled to the surface of the substrate; and a second thermal conductive material different from the first thermal conductive material at least partially overlaying the integrated circuit and overlaying at least a corner of the first opening defined by the first thermal conductive material. In an example, the corner of the first opening defined by the first thermal conductive material includes a portion of a top surface of the first thermal conductive material and a sidewall of the first thermal conductive material.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a substrate;
an integrated circuit electrically coupled to a surface of the substrate;
a first thermal conductive material provided on the surface of the substrate and defining at least one opening to enable the integrated circuit to be electrically coupled to the surface of the substrate; and
a second thermal conductive material different from the first thermal conductive material at least partially overlaying the integrated circuit and overlaying at least a sidewall of the at least one opening defined by the first thermal conductive material.

2. The semiconductor package of claim 1, further comprising a plurality of vias defined by the substrate, wherein the plurality of vias are positioned below the first thermal conductive material.

3. The semiconductor package of claim 2, wherein each of the plurality of vias are filled with the second thermal conductive material or a third thermal conductive material.

4. The semiconductor package of claim 1, further comprising a multi-metal layer at least partially enclosing the substrate, the integrated circuit, the first thermal conductive material and the second thermal conductive material, wherein at least a portion of the first thermal conductive material contacts an inner surface of the multi-metal layer.

5. The semiconductor package of claim 4, further comprising a channel extending from the second thermal conductive material, the channel being filled with the second thermal conductive material and contacting the inner surface of the multi-metal layer.

6. The semiconductor package of claim 1, wherein the first thermal conductive material is a pyrolytic graphite sheet.

7. The semiconductor package of claim 1, wherein the second thermal conductive material is selected from a group comprising silver and copper.

8. The semiconductor package of claim 1, further comprising a NAND die stack coupled to the surface of the substrate, wherein the first thermal conductive material defines another opening to enable the NAND die stack to be coupled to the substrate.

9. A method for fabricating a semiconductor package, comprising:
forming a plurality of vias in a substrate;
laminating a first thermal conductive material on a surface of the substrate, the first thermal conductive material defining at least one opening and covering the plurality of vias;
electrically coupling an integrated circuit to the surface of the substrate within the at least one opening defined by the first thermal conductive material; and
dispensing a second thermal conductive material on the integrated circuit and the first thermal conductive material such that the second thermal conductive material at least partially overlays the integrated circuit and at least partially covers a sidewall of the at least one opening defined by the first thermal conductive material.

10. The method of claim 9, further comprising coupling a NAND die stack to the surface of the substrate, the NAND die stack being coupled to the surface of the substrate within a second opening defined by the first thermal conductive material.

11. The method of claim 10, further comprising encapsulating the NAND die stack, the integrated circuit the first thermal conductive material and the second thermal conductive material with a molding material.

12. The method of claim 11, further comprising forming a channel within the molding material.

13. The method of claim 12, further comprising filling the channel with the second thermal conductive material.

14. The method of claim 13, further comprising forming a multi-metal enclosure around at least a portion of the substrate and the molding material such than an inner surface of the multi-metal enclosure contacts the second thermal conductive material within the channel and at least a portion of the first thermal conductive material.

15. The method of claim 9, further comprising providing a plurality of solder balls on a bottom surface of the substrate.

16. The method of claim 9, wherein the first thermal conductive material is a pyrolytic graphite sheet.

17. The method of claim 9, wherein the second thermal conductive material is selected from a group comprising silver and copper.

18. The method of claim 9, further comprising filling the vias with the second thermal conductive material.

19. A semiconductor package, comprising:
a substrate;
an integrated circuit electrically coupled to a surface of the substrate;
a NAND die stack; coupled to the integrated circuit;
a first thermal conductive material provided on the surface of the substrate and defining a first opening to enable the integrated circuit to be electrically coupled to the surface of the substrate and a second opening to enable a bonding area associated with the NAND die stack to be coupled to the surface of the substrate; and
a second thermal conductive material different from the first thermal conductive material at least partially overlaying the integrated circuit and overlaying at least a corner of the first opening defined by the first thermal conductive material.

20. The semiconductor package of claim 19, wherein the corner of the first opening defined by the first thermal conductive material includes a portion of a top surface of the first thermal conductive material and a sidewall of the first thermal conductive material.
